(19) United States
(12) Patent Application Publication
(10) Pub. No.: US 2015/0203348 A1
(43) Pub. Date: Jul. 23, 2015

(54) FABRICATION OF NANOWIRE ARRAYS

(71) Applicant: President and Fellows of Harvard College, Cambridge, MA (US)

(72) Inventors: Hongkun Park, Lexington, MA (US); Alexander K. Shalek, Cambridge, MA (US); Marsela Jorgolli, Arlington, MA (US)

(21) Appl. No.: 14/422,527

(22) PCT Filed: Mar. 15, 2013
(86) PCT No.: PCT/US2013/032486

§ 371 Date: Feb. 19, 2015

Related U.S. Application Data
(60) Provisional application No. 61/692,017, filed on Aug. 22, 2012.

(51) Int. Cl. B81C 1/00; B01L 99/00; B81B 7/04

(52) U.S. Cl. CPC B81C 1/00111; B81B 7/04; B01L 99/00; B81B 2203/0361; B81B 2207/056; B81B 2201/055

(57) ABSTRACT

The present invention generally relates to nanowire arrays and methods of fabricating such arrays. In certain embodiments, the fabrication methods can consistently form NW arrays with reproducible configurations at nanoscale sites and produce NWs of specified heights, diameters, and densities. In some cases, the methods also allow formation of NW arrays containing barriers between regions, which would be prohibitively expensive if prepared by other methods.

### RELATED APPLICATIONS

This application claims the benefit of U.S. Provisional Patent Application Ser. No. 61/692,017, filed Aug. 22, 2012, entitled “Fabrication of Nanowire Arrays,” by Hongkun Park, et al., incorporated herein by reference.

### GOVERNMENT FUNDING

Research leading to various aspects of the present invention was sponsored, at least in part, by the National Institutes of Health, Contract No. DA035083. The U.S. Government has certain rights in the invention.

### FIELD

The present invention generally relates to nanowire arrays and methods of fabricating and utilizing such arrays.

### BACKGROUND

Nanowires (NWs) provide a powerful new delivery modality for administering biomolecules and compounds directly into cells. Currently, chemical vapor deposition (CVD) is widely used to fabricate arrays of NWs. The process, which involves growing NWs from a precursor material, typically begins by placing or patterning catalyst or seed particles (usually with a diameter of one to a few hundred nanometers) atop a substrate and adding a precursor material to the catalyst or seed particles. When the particles become saturated with the precursor, NWs begin to grow in a shape that minimizes the device's energy. Using CVD, however, it is difficult to control the patterns of nanowires and their heights, diameters, or density. There is a need to develop a method of preparing NW arrays that would allow NW patterns, heights, diameters, and density to be easily controlled. Such a method would permit fabrication of NW arrays that are optimized for effective delivery of biomolecules or compounds into various types of cells.

### SUMMARY

The present invention generally relates to nanowire arrays and methods of fabricating such arrays. The subject matter of the present invention involves, in some cases, interrelated products, alternative solutions to a particular problem, and/or a plurality of different uses of one or more systems and/or articles.

In one aspect, this invention relates to a method of preparing an array of NWs, comprising: providing a substrate; coating the substrate with a positive resist; exposing the resist to a pre-determined pattern of photons or electrons to form a pattern of nanosites; developing the resist so that the pattern of the nanosites is converted to a pattern of nanoholes in the resist; depositing a hard etch mask into each of the nanoholes; uplifting the resist, thereby leaving a pattern of nanospots each covered by the hard etch mask, the pattern of the nanospots being the same as the pattern of the nanoholes; and etching the substrate to a desired depth to yield an array of NWs, in which the hard etch masks protect the covered nanospots and the substrate there beneath from being etched. Nanowires are thereby formed at a plurality of positions arranged in two dimensions and have a local density of 0.001 to 10 nanowires per micrometer² (μm²)

In another aspect, this invention relates to a method comprising: providing a substrate; coating the substrate with a negative resist; exposing the resist to a pre-determined pattern of photons or electrons to form a pattern of nanosites; developing the resist so that the pattern of the nanosites is converted to a pattern of masked nanospots; and etching the substrate to a desired depth to yield an array of NWs at the masked nanospots, whereby the nanowires are formed at a plurality of positions arranged in two dimensions and have a local density of 0.001 to 10 nanowires per micrometer² (μm²).

In some embodiments of the invention, the nanowires are formed in a plurality of columns and a plurality of rows. In certain embodiments, the hard etch mask contains aluminum, aluminum oxide, or a combination thereof. In some embodiments, a protective cover may be applied to one or more regions of the substrate before the etching step, further protecting the regions from being etched. The substrate is a silicon substrate in certain cases. In one set of embodiments, the method further comprises thinning the nanowires to a predetermined diameter.

One aspect of the invention relates to a method of preparing an array of nanowires, comprising: providing a substrate comprising a resist; exposing the resist to a pre-determined pattern of photons or electrons to form a pattern of nanosites; and etching the substrate to produce a plurality of nanowires in the pattern of nanosites. In some embodiments, the nanowires are arrayed on the substrate at a density of at least about 0.001 nanowires per micrometer². The nanowires are arrayed in a repeating pattern in certain cases. In certain embodiments, the nanowires are arrayed in a rectangular pattern. In some cases, the nanowires have an average length of at least about 20 nm.

In another aspect, the present invention is generally directed to an article comprising a substrate comprising at least a first region of nanowires and a second region of nanowires. In some embodiments, an average characteristic of the nanowires of the first region is different than the average characteristic of nanowires in the second region.

In another aspect, the present invention is generally directed to a method of preparing an array of nanowires. In one set of embodiments, the method includes coating a substrate with a resist, exposing the resist to a pre-determined pattern of photons or electrons to form a pattern of nanosites, removing the resist so that the pattern of the nanosites is converted to a pattern of nanoholes in the resist, depositing a metal into each of the nanoholes, removing the resist thereby leaving a pattern of nanospots, the pattern of the nanospots being the same as the pattern of the nanoholes, and etching the substrate to produce an array of nanowires. In another set of embodiments, the method includes coating a substrate with a negative resist, exposing the resist to a pre-determined pattern of photons or electrons to form a pattern of nanosites, developing the resist so that the pattern of the nanosites is converted to a pattern of masked nanospots, and etching the substrate to a desired depth to yield an array of nanowires at the masked nanospots. In some cases, the nanowires are formed at a plurality of positions arranged in two dimensions and have a local density of 0.001 to 10 nanowires per micrometer (μm²).

Additional aspects of the invention relate to arrays of NWs prepared using the methods described above.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1 provides a schematic of a method for fabricating a patterned NW array according to one embodiment of the invention.

FIG. 2 provides images demonstrating that NWs can be fabricated with consistent geometries at a specified density over a large area.

FIG. 3 provides images showing that the diameter of the patterned NWs can be controlled within a few tens of nanometers by repeated oxidation and oxide removal.

FIG. 4 provides images demonstrating that different thinning strategies can be used to define NW shape and profile.

FIG. 5 provides a schematic of a method for fabricating a patterned array with partitioned NW areas that can have different densities of NWs, enabling a wide variety of different molecules to be assayed in parallel using a small area and a small number of cells, thus enabling high-throughput screens.

### DETAILED DESCRIPTION

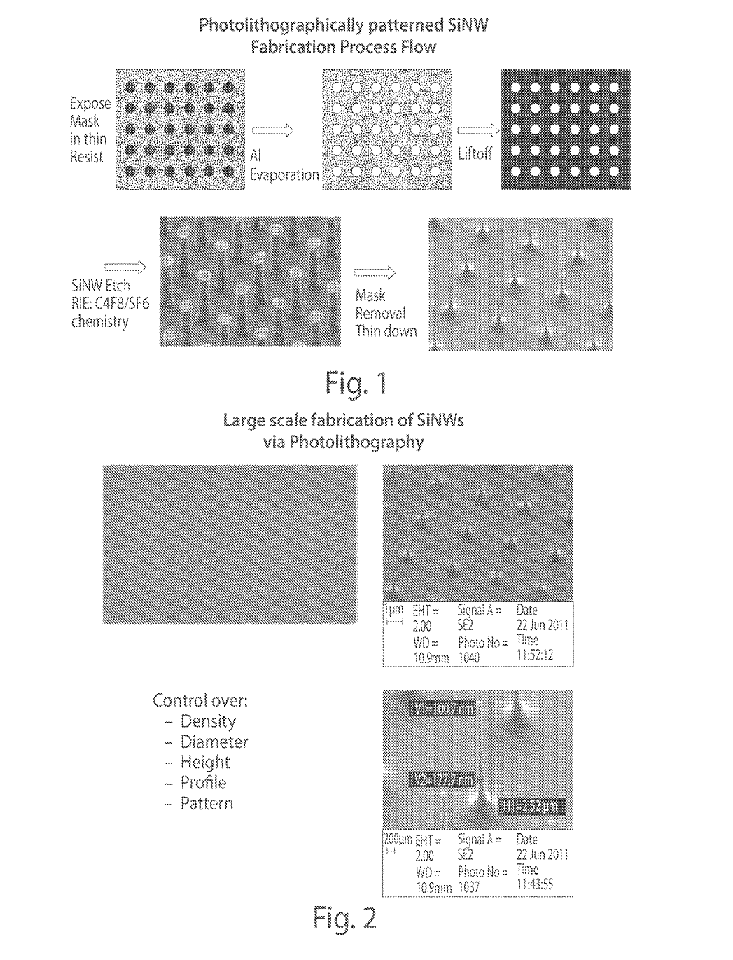

The present invention generally relates to nanowire arrays and methods of fabricating such arrays. In certain embodiments, the fabrication methods can consistently form NW arrays with reproducible configurations at nanoscale sites and produce NWs of specified heights, diameters, and densities. In some cases, the methods also allow formation of NW arrays containing barriers between regions, which would be prohibitively expensive if prepared by other methods. FIG. 1 provides a schematic depiction of a method for fabricating a patterned NW array according to one embodiment of the invention.

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Various aspects of this invention involve an array of upstanding nanowires. On average, the upstanding nanowires may form an angle with respect to a substrate of between about 80° and about 100°, between about 85° and about 95°, or between about 88° and about 92°. In some cases, the average angle is about 90°. As used herein, the term “nanowire” (or “NW”) refers to a material in the shape of a wire or rod having a diameter in the range of 1 nm to 1 micrometer (μm). The NWs may be formed from materials with low cytotoxicity; suitable materials include, but are not limited to, silicon, silicon oxide, silicon nitride, silicon carbide, iron oxide, aluminum oxide, iridium oxide, tungsten, stainless steel, silver, platinum, and gold. Other suitable materials include aluminum, copper, molybdenum, tantalum, titanium, nickel, tungsten, chromium, or palladium. In some embodiments, the nanowire comprises or consists essentially of a semiconductor. Typically, a semiconductor is an element having semiconductive or semi-metallic properties (i.e., between metallic and non-metallic properties). An example of a semiconductor is silicon. Other non-limiting examples include elemental semiconductors, such as gallium, germanium, diamond (carbon), tin, selenium, tellurium, boron, or phosphorous. In other embodiments, more than one element may be present in the nanowires as the semiconductor, for example, gallium arsenide, gallium nitride, indium phosphide, cadmium selenide, etc.

The size and density of the NWs in the NW arrays may be varied; the lengths, diameters, and density of the NWs can be configured to permit adhesion and penetration of cells. In some embodiments, the length of the NWs can be 0.1-10 micrometers (μm). In some cases, the diameter of the NWs can be 50-300 nm. In certain embodiments, the density of the NWs can be 0.05-5 NWs per micrometer (μm²). Other examples are discussed below.

The nanowires may have any suitable length, as measured moving away from the substrate. The nanowires may have substantially the same lengths, or different lengths in some cases. For example, the nanowires may have an average length of at least about 0.1 micrometers, at least about 0.2 micrometers, at least about 0.3 micrometers, at least about 0.5 micrometers, at least about 0.7 micrometers, at least about 1 micrometer, at least about 2 micrometers, at least about 3 micrometers, at least about 5 micrometers, at least about 7 micrometers, or at least about 10 micrometers. In some cases, the nanowires may have an average length of no more than about 10 micrometers, no more than about 7 micrometers, no more than about 5 micrometers, no more than about 3 micrometers, no more than about 2 micrometers, no more than about 1 micrometer, no more than about 0.7 micrometers, no more than about 0.5 micrometers, no more than about 0.3 micrometers, no more than about 0.2 micrometers, or no more than about 0.1 micrometers. Combinations of any of these are also possible in some embodiments.

The nanowires may also have any suitable diameter, or narrowest dimension if the nanowires are not circular. The nanowires may have substantially the same diameters, or in some cases, the nanowires may have different diameters. In some cases, the nanowires may have an average diameter of at least about 10 nm, at least about 30 nm, at least about 50 nm, at least about 70 nm, at least about 100 nm, at least about 200 nm, at least about 300 nm, etc., and/or the nanowires may have an average diameter of no more than about 300 nm, no more than about 200 nm, no more than about 100 nm, no more than about 70 nm, no more than about 50 nm, no more than about 30 nm, no more than about 20 nm, or no more than about 10 nm, or any combination of these. The substrate may be formed of the same or different materials as the nanowires.

For example, the substrate may comprise silicon, silicon oxide, silicon nitride, silicon carbide, iron oxide, aluminum oxide, iridium oxide, tungsten, stainless steel, silver, platinum, gold, gallium, germanium, or any other materials described herein that a nanowire may be formed from. In one embodiment, the substrate is formed from a semiconductor.

In some embodiments, arrays of NWs on a substrate may be obtained by growing NWs from a precursor material. As a non-limiting example, chemical vapor deposition (CVD) may be used to grow NWs by placing or patterning catalyst or seed particles (typically with a diameter of 1 nm to a few hundred nm) atop a substrate and adding a precursor to the catalyst or seed particles. When the particles become saturated with the precursor, NWs can begin to grow in a shape that minimizes the system's energy. By varying the precursor, substrate, catalyst/seed particles (e.g., size, density, and deposition method on the substrate), and growth conditions, NWs can be made in a variety of materials, sizes, and shapes, at sites of choice.

In certain embodiments, arrays of NWs on a substrate may be obtained by growing NWs using a top-down process that involves removing predefined structures from a supporting substrate. As a non-limiting example, the sites where NWs are to be formed may be patterned into a soft mask and subsequently etched to develop the patterned sites into three-dimensional nanowires. Methods for patterning the soft mask include, but are not limited to, photolithography and electron beam lithography. The etching step may be either wet or dry.

Some aspects of the invention are directed to coating the substrate with a positive resist. As used herein, “positive resist” refers to a material that becomes soluble to a resist developer after being exposed to a beam of photons or electrons. When a beam of photons is used, the technique is generally termed photolithography, and when a beam of electrons is used, the technique is generally referred to as electron beam lithography. Examples of positive resists used in photolithography include, but are not limited to, poly(methyl methacrylate) (PMMA) and SPR220, S1800, and ma-P1200 series photoresists. Other examples of photoresists include, but are not limited to, SU-8, S1805, LOR 3A, poly(methyl glutarimide), phenol formaldehyde resin (diazonaphthoquinone/novolac), diazonaphthoquinone (DNQ), Hoechst AZ 4620, Hoechst AZ 4562, Shipley 1400-17, Shipley 1400-27, Shipley 1400-37, or the like. Examples of positive resists used in electron beam lithography include, but are not limited to, PMMA, ZEP 520, APEX-E, EBR-9, and UVS. In some embodiments, portions of the resist may be exposed to light (visible, UV, etc.), electrons, ions, X-rays, etc. (e.g., projected onto the photoresist), and the exposed portions can be etched away (e.g., using suitable etchants, plasma, etc.) to produce a suitable pattern.

Certain aspects of the invention are directed to methods comprising coating the substrate with a negative resist. As used herein, “negative resist” refers to a material that becomes less soluble to a resist developer after being exposed to a beam of photons or electrons. Several non-limiting examples of negative resists used in photolithography include SU-8 series photoresists, KMPR 1000, and UVN30. Additional non-limiting examples of negative resists used in electron beam lithography include hydrogen silsesquioxane (HSQ) and NEB-31.

It should be appreciated that any positive resist, negative resist, or resist developer known in the art may be used. Resist developers for photolithography include aqueous solutions with either an organic compound such as tetramethylammonium hydroxide or an inorganic salt such as potassium hydroxide, and they may also contain surfactants. Resist developers for electron beam lithography may include methyl isobutyl ketone and isopropyl alcohol.

In addition, certain aspects of the invention relate to methods that comprise exposing a substrate that has been coated with a positive or negative resist to a pre-determined pattern of photon or electron beams to form a pattern of nanosites. In some aspects of the invention, the pattern may be a repeating pattern. In certain cases, the pattern may be a rectangular pattern.

For example, the nanowires may be regularly positioned within a rectangular grid with periodic spacing, e.g., having a periodic spacing of at least about 0.01 micrometers, at least about 0.03 micrometers, at least about 0.05 micrometers, at least about 0.1 micrometers, at least about 0.3 micrometers, at least about 0.5 micrometers, at least about 1 micrometer, at least about 2 micrometers, at least about 3 micrometers, at least about 5 micrometers, at least about 10 micrometers, etc. In some cases, the periodic spacing may be no more than about 10 micrometers, no more than about 5 micrometers, no more than about 3 micrometers, no more than about 1 micrometer, no more than about 0.5 micrometers, no more than about 0.3 micrometers, no more than about 0.1 micrometers, no more than about 0.05 micrometers, no more than about 0.03 micrometers, no more than about 0.01 micrometers, etc. Combinations of these are also possible, e.g., the array may have a periodic spacing of nanowires of between about 0.01 micrometers and about 0.03 micrometers.

In some cases, the nanowires (whether regularly or irregularly spaced) may be positioned on the substrate such that the average distance between a nanowire and its nearest neighboring nanowire is at least about 0.01 micrometers, at least about 0.03 micrometers, at least about 0.05 micrometers, at least about 0.1 micrometers, at least about 0.3 micrometers, at least about 0.5 micrometers, at least about 1 micrometer, at least about 2 micrometers, at least about 3 micrometers, at least about 5 micrometers, at least about 10 micrometers, etc. In some cases, the distance may be no more than about 10 micrometers, no more than about 5 micrometers, no more than about 3 micrometers, no more than about 1 micrometer, no more than about 0.5 micrometers, no more than about 0.3 micrometers, no more than about 0.1 micrometers, no more than about 0.05 micrometers, no more than about 0.03 micrometers, no more than about 0.01 micrometers, etc. In some cases, the average distance may fall within any of these values, e.g., between about 0.5 micrometers and about 2 micrometers.

Some embodiments of the invention are directed to developing a positive resist so that the pattern of nanosites is converted to a pattern of nanoholes in the resist. In some of those embodiments, a hard etch mask is subsequently deposited into each of the nanoholes. In some embodiments, the hard etch mask comprises or consists essentially of a metal such as aluminum oxide, aluminum, or a combination thereof. The resist is then uplifted or removed, leaving a pattern of nanospots each covered by a hard etch mask, the pattern of the nanospots being the same as the pattern of the nanoholes. In certain embodiments, the substrate is then etched to a desired depth to yield an array of nanowires, the hard etch masks protecting the covered nanospots and substrate lying beneath from being etched. Nanowires are thereby formed at a plurality of positions arranged in two dimensions and have a local density of 0.001 to 10 nanowires per micrometer² (μm²). FIG. 2 illustrates large scale fabrication of NW arrays using an embodiment of the invention.

Some embodiments of the invention are directed to developing a negative resist so that the pattern of nanosites is converted to a pattern of masked nanospots. In some cases, the substrate is subsequently etched to a desired depth to yield an array of nanowires at the masked nanospots, thereby forming nanowires at a plurality of positions arranged in two dimensions and having a local density of 0.001-10 nanowires per micrometer² (μm²).

In addition, in some cases, the density of nanowires on the substrate, or on a region of the substrate defined by nanowires, may be at least about 0.01 nanowires per square micrometer, at least about 0.02 nanowires per square micrometer, at least about 0.03 nanowires per square micrometer, at least about 0.05 nanowires per square micrometer, at least about 0.07 nanowires per square micrometer, at least about 0.1 nanowires per square micrometer, at least about 0.2 nanowires per square micrometer, at least about 0.3 nanowires per square micrometer, at least about 0.5 nanowires per square micrometer, at least about 0.7 nanowires per square micrometer, at least about 1 nanowire per square micrometer, at least about 2 nanowires per square micrometer, at least about 3 nanowires per square micrometer, at least about 4 nanowires per square micrometer, at least about 5 nanowires per square micrometer, etc. In addition, in some embodiments, the density of nanowires on the substrate may be no more than about 10 nanowires per square micrometer, no more than about 5 nanowires per square micrometer, no more than about 4 nanowires per square micrometer, no more than about 3 nanowires per square micrometer, no more than about 2 nanowires per square micrometer, no more than about 1 nanowire per square micrometer, no more than about 0.7 nanowires per square micrometer, no more than about 0.5 nanowires per square micrometer, no more than about 0.3 nanowires per square micrometer, no more than about 0.2 nanowires per square micrometer, no more than about 0.1 nanowires per square micrometer, no more than about 0.07 nanowires per square micrometer, no more than about 0.05 nanowires per square micrometer, no more than about 0.03 nanowires per square micrometer, no more than about 0.02 nanowires per square micrometer, or no more than about 0.01 nanowires per square micrometer.

In certain aspects, the substrate may comprise more than one region of nanowires, e.g., patterned as discussed herein. For example, a pre-determined pattern of photons or electrons may be used to produce a substrate comprising a first region of nanowires and a second region of nanowires. In addition, in some cases, more than two such regions of nanowires may be produced on a substrate. For example, there may be at least 3, at least 6, at least 10, at least 15, at least 20, at least 50, or at least 100 separate regions of nanowires on a substrate. In some cases, the regions are separate from each other. Any number of nanowires may be present in a region, e.g., at least about 10, at least about 20, at least about 50, at least about 100, at least about 300, at least about 1000, etc. The nanowires may be present in any suitable configuration or array, e.g., in a rectangular or a square array.

The nanowires in a first region and a second region may be the same, or there may be one or more different characteristics between the nanowires. For example, the nanowires in the first region and the second region may have different average diameters, lengths, densities, biological effectors, or the like. If more than two regions of nanowires are present on the substrate, each of the regions may independently be the same or different.

As discussed, several aspects of this invention involve etching of the substrate. Additional non-limiting examples of suitable etching processes that may be used in some embodiments include reactive-ion etching, deep reactive-ion etching, wet etching with acid (e.g., hydrofluoric acid), and plasma etching.

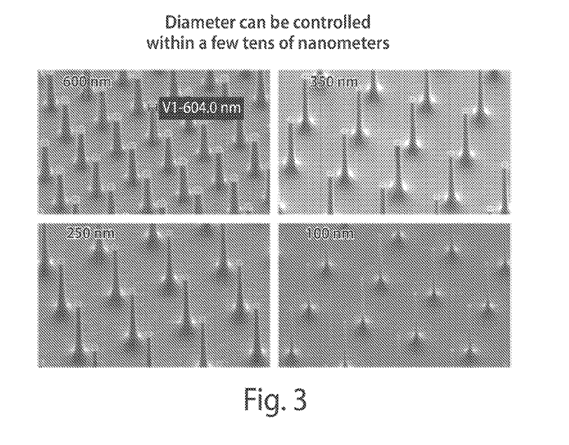

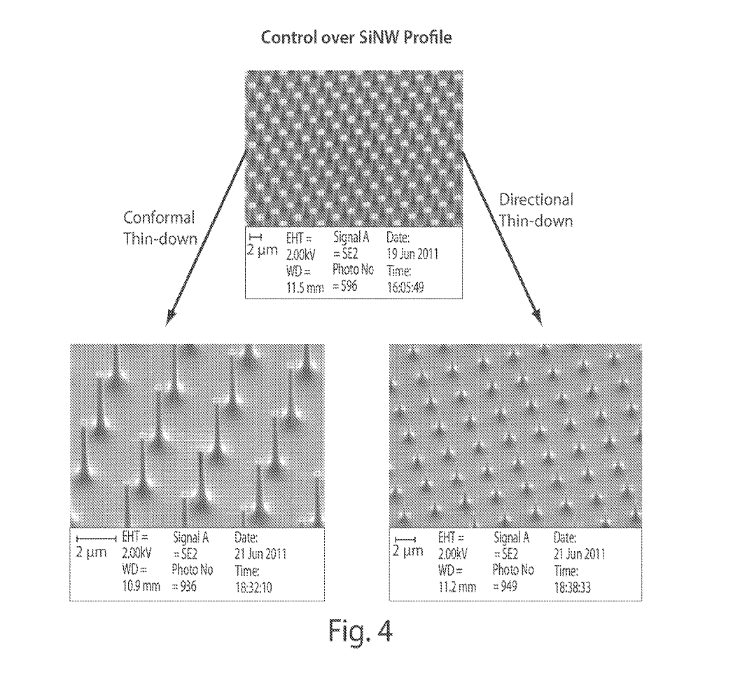

In some embodiments, the nanowire diameters are reduced by oxidizing and subsequently etching away the formed oxide. Any oxidizing or etching method known in the art may be used. A non-limiting example of an oxidizing method is thermal oxidizing. The process of oxidizing and etching away the formed oxide may be repeated as needed to obtain the desired nanowire diameters. FIG. 3 shows images demonstrating that NW diameter can be controlled within tens of nanometers, and FIG. 4 shows how different methods of thinning down (e.g., conformal and directional thin-down) may be used to obtain NWs of different shapes and sizes.

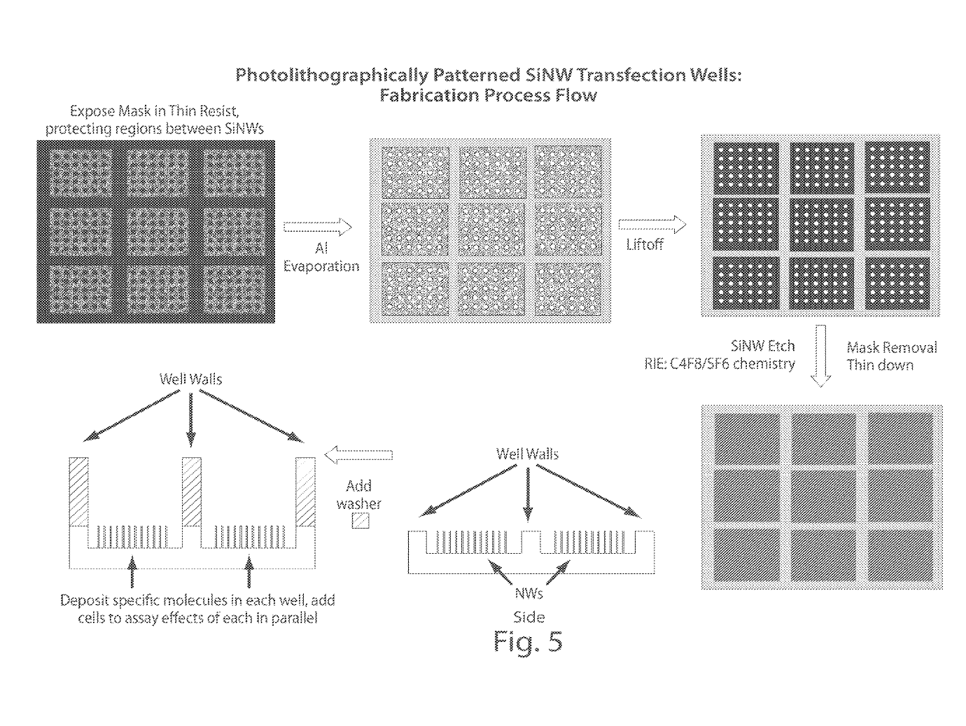

In some aspects of the invention, NWs can be arranged into patterned NW wells that may be useful in high-throughput screening. To obtain patterned NW wells, regions without NWs may be generated by selectively protecting regions of the substrate prior to the etching step in the NW array fabrication process. This enables the delineation of active delivery areas containing NWs and non-delivery regions. The active areas can be isolated from one another to generate transfection wells by, for example, affixing washers to the surface of the substrate. FIG. 5 shows a schematic for fabrication of a substrate with nine partitioned regions of nanowires separated by washers. However, other numbers of partitioned regions may be used in other embodiments of the invention. For example, there may be at least 2, at least 3, at least 5, at least 10, at least 15, or at least 20 such regions on a substrate. In some cases, there are no more than 100 or no more than 50 such regions on a substrate.

In one set of embodiments, at least some of the NWs may be used to deliver a molecule of interest into a cell, e.g., through insertion of a NW into the cell. In certain embodiments of the invention, at least some of the NWs may undergo surface modification so that molecules of interest can be attached to them. It should be appreciated that the NWs can be complexed with various molecules according to any method known in the art. It should also be appreciated that the molecules connected to different NWs may be distinct. In some embodiments, a NW may be attached to a molecule of interest through a linker. The interaction between the linker and the NW may be covalent, electrostatic, photosensitive, or hydrolysable. As a specific non-limiting example, a silane compound may be applied to a NW with a surface layer of silicon oxide, resulting in a covalent Si—O bond. As another specific non-limiting example, a thiol compound may be applied to a NW with a surface layer of gold, resulting in a covalent Au—S bond. Examples of compounds for surface modification include, but are not limited to, aminosilanes such as (3-aminopropyl)-trimethoxysilane, (3-aminopropyl)-triethoxysilane, 3-(2-aminoethylamino)propyl-dimethoxymethylsilane, (3-aminopropyl)-diethoxy-methylsilane, [3-(2-aminoethylamino)propyl]trimethoxysilane, bis[3-(trimethoxysilyl)propyl]amine, and (11-aminoundecyl)-triethoxysilane; glycidoxysilanes such as 3-glycidoxypropyldimethylethoxysilane and 3-glycidyloxypropyl)trimethoxysilane; mercaptosilanes such as (3-mercaptopropyl)-trimethoxysilane and (11-mercaptoundecyl)-trimethoxysilane; and other silanes such as trimethoxy(octyl)silane, trichloro(propyl)silane, trimethoxyphenylsilane, trimethoxy(2-phenylethyl)silane, allyltriethoxysilane, allyltrimethoxysilane, 3-[bis(2-hydroxyethyl)amino]propyl-triethoxydilane, 3-(trichlorosilyl)propyl methacrylate, and (3-bromopropyl)trimethoxysilane. Other non-limiting examples of compounds that may be used to form the linker include poly-lysine, collagen, fibronectin, and laminin.

In addition, in various embodiments, a nanowire may be prepared for binding or coating of a suitable biological effector by activating the surface of the nanowire, silanizing at least a portion of the nanowire, and reacting a crosslinker to the silanized portions of the nanowire. Methods for activating the surface include, but are not limited to, surface oxidation, such as by plasma oxidation or acid oxidation. Non-limiting examples of suitable types of crosslinkers that are commercially available and known in the art include maleimides, histidines, haloacetyls, and pyridyldithiols.

Similarly, the interaction between the linker and the molecule to be delivered can be covalent, electrostatic, photosensitive, or hydrolysable. In some embodiments, a molecule of interest attached to or coated on a NW may be a biological effector. As used herein, a “biological effector” refers to a substance that is able to modulate the expression or activity of a cellular target. It includes, but is not limited to, a small molecule, a protein (e.g., a natural protein or a fusion protein), an enzyme, an antibody (e.g., a monoclonal antibody), a nucleic acid (e.g., DNA, including linear and plasmid DNAs; RNA, including mRNA, siRNA, and microRNA), and a carbohydrate. The term “small molecule” refers to any molecule with a molecular weight below 1000 Da. Non-limiting examples of molecules that may be considered to be small molecules include synthetic compounds, drug molecules, oligosaccharides, oligonucleotides, and peptides. The term “cellular target” refers to any component of a cell. Non-limiting examples of cellular targets include DNA, RNA, a protein, an organelle, a lipid, or the cytoskeleton of a cell. Other examples include the lysosome, mitochondria, ribosome, nucleus, or the cell membrane.

In some cases, the nanowires can be used to deliver biological effectors or other suitable biomolecular cargo into a population of cells at surprisingly high efficiencies. Furthermore, such efficiencies may be achieved regardless of cell type, as the primary mode of interaction between the nanowires and the cells is physical insertion, rather than biochemical interactions (e.g., as would appear in traditional pathways such as phagocytosis, receptor-mediated endocytosis, etc.). For instance, in a population of cells on the surface of the substrate, at least about 50%, at least about 60%, at least about 70%, at least about 80%, or at least about 90% of the cells may have at least one nanowire inserted therein. In some cases, as discussed herein, the nanowires may have at least partially coated thereon one or more biological effectors. Thus, in some embodiments, biological effectors may be delivered to at least about 50%, at least about 60%, at least about 70%, at least about 80%, or at least about 90% of the cells on the substrate, e.g., via the nanowires.

In one set of embodiments, the surface of the substrate may be treated in any fashion that allows binding of cells to occur thereto. For example, the surface may be ionized and/or coated with any of a wide variety of hydrophilic and/or cytophilic materials, for example, materials having exposed carboxylic acid, alcohol, and/or amino groups. In another set of embodiments, the surface of the substrate may be reacted in such a manner as to produce carboxylic acid, alcohol, and/or amino groups on the surface. In some cases, the surface of the substrate may be coated with a biological material that promotes adhesion or binding of cells, for example, materials such as fibronectin, laminin, vitronectin, albumin, collagen, or peptides or proteins containing RGD sequences.

It should be understood that for a cell to adhere to the nanowire, a separate chemical or “glue” is not necessarily required. In some cases, sufficient nanowires may be inserted into a cell such that the cell cannot easily be removed from the nanowires (e.g., through random or ambient vibrations), and thus, the nanowires are able to remain inserted into the cells. In some cases, the cells cannot be readily removed via application of an external fluid after the nanowires have been inserted into the cells.

In some cases, merely placing or plating the cells on the nanowires is sufficient to cause at least some of the nanowires to be inserted into the cells. For example, a population of cells suspended in media may be added to the surface of the substrate containing the nanowires, and as the cells settle from being suspended in the media to the surface of the substrate, at least some of the cells may encounter nanowires, which may (at least in some cases) become inserted into the cells.

Once the molecules have been attached to the nanowires, the nanowires can be used to deliver a broad range of biological effectors into a wide variety of clonal and primary cells, even those that are traditionally difficult to transfect. The NWs can therefore be used for basic biological purposes, including assessing the functional consequences of knocking down a specific gene, and applied ends, such as testing the efficacy of a pharmaceutical agent.

In particular, the patterned NW wells may be suitable for efficient and effective high-throughput screening of molecular perturbants, either alone or in combination, in a small footprint with a limited number of cells. More specifically, the patterned NW wells can be used in whole genome wide siRNA or pharmaceutical library screens for rapid identification of both salient molecules in biological processes (e.g., the genes crucial for Th17 T cell differentiation) and targets for clinical ends (e.g., killing cancer cells). Different molecular reagents can be deposited within these wells (e.g., by pipetting and by microarraying) and then, cells can be added to all wells. The consequences of delivering different molecules, either alone or in combination, can be assayed in parallel. This high-throughput screening process enables screening of a small amount of a molecule across multiple cell types as different cells can be spotted onto different areas.

There are various advantages in using the patterned NW wells for high-throughput screening. For instance, one SiNW-well wafer can be used to screen a large number of molecules. For example, when wells of 175 micrometers (μm) by 175 micrometers (μm) are generated at 200 micrometer (μm) pitch, 25 wells can fit in a square mm, and more than 400,000 wells can fit onto a standard 6 inch silicon wafer. This means that over 400,000 different molecules (of the same or different species) or combinations thereof can be screened simultaneously using one SiNW wafer. As mentioned, in some cases, the substrate may contain multiple regions of nanowires. In some cases, regions of nanowires can be used to reduce reagent and cell requirements, e.g., if they are positioned closely to each other and/or share the same substrate. In some embodiments, a full wafer (or other substrate) can be trimmed to any shape (e.g., with a dicing saw) to enable compatibility with different high-throughput screening platforms (e.g., optical microscopes).

The following documents are incorporated herein by reference in their entireties: U.S. patent application Ser. No. 13/264,587, filed Oct. 14, 2011, entitled “Molecular Delivery with Nanowires,” by Park, et al., published as U.S. Patent Application Publication No. 2012/0094382 on Apr. 19, 2012; International Patent Application No. PCT/US11/53640, filed Sep. 28, 2011, entitled “Nanowires for Electrophysiological Applications,” by Park, et al., published as WO 2012/050876 on Apr. 19, 2012; International Patent Application No. PCT/US2011/53646, filed Sep. 28, 2011, entitled “Molecular Delivery with Nanowires,” by Park, et al., published as WO 2012/050881 on Apr. 19, 2012; U.S. Provisional Patent Application Ser. No. 61/684,918, filed Aug. 20, 2012, entitled “Use of Nanowires for Delivering Biological Effectors into Immune Cells,” by Park, et al.; and U.S. Provisional Patent Application Ser. No. 61/692,017, filed Aug. 22, 2012, entitled “Fabrication of Nanowire Arrays,” by Park, et al. In addition, the following PCT applications, each filed on Mar. 15, 2013, are incorporated herein by reference in their entireties: “Use of Nanowires for Delivering Biological Effectors into Immune Cells,” by Park, et al.; and “Microwell Plates Containing Nanowires,” by Park, et al.

A person skilled in the art can determine without undue experimentation the patterns and intensities of light, the heights, the densities, and the diameters of the NWs, the etching conditions, as well as other conditions. Without further elaboration, it is believed that one skilled in the art can, based on the description herein, utilize the present invention to its fullest extent. All publications cited herein are incorporated by reference in their entirety.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements.

This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. A method of preparing an array of nanowires, the method comprising:
providing a substrate,
coating the substrate with a positive resist,
exposing the resist to a pre-determined pattern of photons or electrons to form a pattern of nanosites,
developing the resist so that the pattern of the nanosites is converted to a pattern of nanoholes in the resist,
depositing a hard etch mask into each of the nanoholes,
uplifting the resist thereby leaving a pattern of nanospots each covered by the hard etch mask, the pattern of the nanospots being the same as the pattern of the nanoholes, and
etching the substrate to a desired depth to yield an array of nanowires, the hard etch masks protecting the covered nanospots and the substrate beneath there from being etched,
whereby the nanowires are formed at a plurality of positions arranged in two dimensions and have a local density of 0.001 to 10 nanowires per micrometer (μm²).

2. The method of claim 1, wherein the nanowires are formed in a plurality of columns and a plurality of rows.

3. The method of any one of claim 1 or 2, wherein the hard etch mask contains aluminum, aluminum oxide, or a combination thereof.

4. The method of any one of claims 1-3, further comprising, before the etching step, applying a protective cover to one or more regions of the substrate, thereby further protecting the regions from being etched.

5. The method of any one of claims 1-4, wherein the substrate is a silicon substrate.

6. An array of nanowires prepared by the method of any one of claims 1-5.

7. The method of any one of claims 1-5, wherein the hard etch mask contains aluminum, aluminum oxide, or a combination thereof.

8. The method of any one of claim 1-5 or 7, further comprising thinning the nanowires formed to a predetermined diameter.

9. The method of any one of claim 1-5, 7, or 8, further comprising, before the etching step, applying a protective cover to one or more regions of the substrate, thereby further protecting the regions from being etched.

10. An array of nanowires prepared by the method of any one of claims 7-9.

11. A method of preparing an array of nanowires, the method comprising:
providing a substrate,
coating the substrate with a negative resist,
exposing the resist to a pre-determined pattern of photons or electrons to form a pattern of nanosites,
developing the resist so that the pattern of the nanosites is converted to a pattern of masked nanospots, and
etching the substrate to a desired depth to yield an array of nanowires at the masked nanospots,
whereby the nanowires are formed at a plurality of positions arranged in two dimensions and have a local density of 0.001 to 10 nanowires per micrometer (μm²).

12. The method of claim 11, wherein the nanowires are formed in a plurality of columns and a plurality of rows.

13. The method of any one of claim 11 or 12, further comprising, before the etching step, applying a protective cover to one or more regions of the substrate, thereby further protecting the regions from being etched.

14. The method of any one of claims 11-13, wherein the substrate is a silicon substrate.

15. An array of nanowires prepared by the method of any one of claims 11-14.

16. The method of any one of claims 11-14, further comprising thinning the nanowires formed to a predetermined diameter.

17. The method of any one of claim 11-14 or 16, further comprising, before the etching step, applying a protective cover to one or more regions of the substrate, thereby further protecting the regions from being etched.

18. An array of nanowires prepared by the method of any one of claim 16 or 17.

19. A method of preparing an array of nanowires, comprising:
providing a substrate comprising a resist;
exposing the resist to a pre-determined pattern of photons or electrons to form a pattern of nanosites on the substrate; and
etching the substrate to produce a plurality of nanowires in the pattern of nanosites.

20. The method of claim 19, wherein the nanowires are arrayed on the substrate at a density of at least 0.001 nanowires per micrometer².

21. The method of any one of claim 19 or 20, wherein the nanowires are arrayed in a repeating pattern.

22. The method of any one of claims 19-21, wherein the nanowires are arrayed in a rectangular pattern.

23. The method of any one of claims 19-22, wherein the nanowires have an average length of at least about 20 nm.

24. A method of preparing an array of nanowires, the method comprising:
coating a substrate with a resist,
exposing the resist to a pre-determined pattern of photons or electrons to form a pattern of nanosites,
removing the resist so that the pattern of the nano sites is converted to a pattern of nanoholes in the resist,
depositing a metal into each of the nanoholes,
removing the resist thereby leaving a pattern of nanospots, the pattern of the nanospots being the same as the pattern of the nanoholes, and
etching the substrate to produce an array of nanowires.

25. A method of preparing an array of nanowires, the method comprising:
coating a substrate with a negative resist,
exposing the resist to a pre-determined pattern of photons or electrons to form a pattern of nanosites,
developing the resist so that the pattern of the nanosites is converted to a pattern of masked nanospots, and
etching the substrate to a desired depth to yield an array of nanowires at the masked nanospots,
whereby the nanowires are formed at a plurality of positions arranged in two dimensions and have a local density of 0.001 to 10 nanowires per micrometer (μm²).

26. An article, comprising:
a substrate comprising at least a first region of nanowires and a second region of nanowires, wherein an average characteristic of the nanowires of the first region is different than the average characteristic of nanowires in the second region.

27. The article of claim 26, wherein the first region comprises at least about 100 nanowires.

28. The article of any one of claim 26 or 27, wherein the second region comprises at least about 100 nanowires.

29. The article of any one of claims 26-28, wherein the first region is substantially rectangular.

30. The article of any one of claims 26-29, wherein the second region is substantially rectangular.

31. The article of any one of claims 26-30, wherein the average length of the nanowires in the first region is greater than the average length of the nanowires in the second region.

32. The article of any one of claims 26-31, wherein the average diameter of the nanowires in the first region is greater than the average diameter of the nanowires in the second region.

33. The article of any one of claims 26-32, wherein the density of nanowires in the first region is greater than the density of nanowires in the second region.

34. The article of any one of claims 26-33, wherein at least some of the nanowires are silicon nanowires.

35. The article of any one of claims 26-34, wherein the average length of the nanowires of the first region is 0.1-10 micrometers (μm).

36. The article of any one of claims 26-35, wherein the average diameter of the nanowires of the first region is 50-300 nm.

37. The article of any one of claims 26-36, wherein the density of the nanowires of the first region is 0.05-5 nanowires per micrometer (μm²).

38. The article of any one of claims 26-37, wherein the nanowires of the first region are at least partially coated with a biological effector.

39. The article of claim 38, wherein the biological effector is a small molecule, a DNA molecule, an RNA molecule, or a protein.

40. The method of any one of claim 38 or 39, wherein the nanowires of the second region are at least partially coated with a second biological effector different from the first biological effector.
